(19) United States
(12) Patent Application Publication
(10) Pub. No.: US 2012/0175744 A1
(43) Pub. Date: Jul. 12, 2012

(54) COPPER ELECTROPLATING COMPOSITION

(75) Inventors: Chien-Hsun Lai, Hsinchu City 300 (TW); Tzu-Tsang Huang, Shinchu City 300 (TW); Shao-Min Yang, Taoyuan City (TW); ChiaoHao Chan, Jhubei City (TW)

(73) Assignee: BASF SE, Ludwigshafen (DE)

(21) Appl. No.: 13/395,041

(22) PCT Filed: Sep. 15, 2010
(86) PCT No.: PCT/EP2010/063505

§ 371 Date: Mar. 8, 2012

Related U.S. Application Data
(60) Provisional application No. 61/246,162, filed on Sep. 28, 2009.

(51) Int. Cl. H01L 23/48; C25D 3/38

(52) U.S. Cl. 257/621; 205/296; 257/E23.011

(57) ABSTRACT

The present invention relates to a copper electroplating composition comprising a copper alkanesulfonate salt, a free alkanesulfonic acid, and one or more organic compounds selected from the group consisting of suppressors, accelerators, levelers, and mixtures thereof, in which the concentration of free acid is from 0 M to about 0.25 M and the composition is free of halide ions. The present invention also relates to a process of metalizing micro-sized trenches or vias in a substrate using the composition.

### FIELD OF THE INVENTION

The present invention relates to a copper electroplating composition and a process for electrolytic copper metallization of micro sized trenches or vias in silicon wafers in the manufacture of semiconductor integrated circuit (IC) devices. In particular, the invention relates to a copper electroplating composition and a process for through silicon vias (TSV) in semiconductor devices.

### BACKGROUND OF THE INVENTION

### Description of the Prior Art

Copper electroplating is a method of depositing copper on conductive substrates by passing an electric current between two electrodes in an electroplating solution. Commercial copper electroplating solutions typically include a copper source, an acid, and various additives. The copper source is a soluble copper salt such as copper sulfate, copper fluoroborate, and copper cyanide. The acid is generally of the same anion used with the copper source. Additives such as suppressors, accelerators, and levelers are used to improve the properties of copper deposit. The most widely used commercial copper electroplating solution is based on an aqueous solution of copper sulfate, sulfuric acid and various additives. In addition, other inorganic additives may be added, such as halides including a chloride ion(s).

More recently, copper electroplating also has been employed in semiconductor integrated circuit device manufacturing to provide chip interconnections, replacing aluminum conductors. Demand for better performance, increased miniaturization, and greater circuit density has led to substantial reductions in the size of microelectronic devices. Further enhancements to density and miniaturization may require reductions to the dimensions of interconnecting features such as the vias or trenches that are formed in a substrate and filled with a bulk material such as copper.

The use of alkanesulfonic acids in copper electroplating is also known. U.S. Pat. No. 6,605,204 discloses the electrolytic deposition of copper onto electronic devices using a solution comprising copper alkanesulfonate salts and free alkanesulfonic acids, in which the solution is for the metallization of micro- or submicro-dimensioned trenches or vias. However, U.S. Pat. No. 6,605,204 does not provide any examples showing that metallization of vias or trenches has been achieved.

Moreover, US 2009/0035940 provides a method for metalizing a through silicon via feature in a semiconductor integrated circuit device substrate comprising immersing the substrate into an electrolytic copper deposition composition comprising (a) a source of copper ions; (b) an acid; (c) one or more organic compounds selected from among polarizers and/or depolarizers; and (d) chloride ions. The method employs step current density plating, in which initiation preferably occurs at a relatively low current density and in which the current density is increased after a period of copper deposition.

The inventors of the present invention observed that the copper electroplating composition of the present invention is halide ion free and can achieve void-free and seam-free filling with a high deposition rate in conditions of zero or low free acid concentration. Moreover, the process using the composition of the present invention employs a one-step current plating without changing current density. In particular, the process is suitable for being carried out at high current density, which can shorten the plating time.

### SUMMARY OF THE INVENTION

The present invention is directed to a copper electroplating composition for the metallization of micro-sized trenches or vias in a substrate, which comprises:

(1) a copper alkanesulfonate salt;

(2) a free alkanesulfonic acid; and

(3) one or more organic compounds selected from the group consisting of suppressors, accelerators, levelers, brighteners, and mixtures thereof, wherein the concentration of free acid is from 0 M to about 0.25 M and the composition is free of halide ions.

The present invention is further directed to a process of metalizing micro-sized trenches or vias in a substrate, comprising immersing the substrate into the copper electroplating composition of the present invention and providing electrical current through the composition to electroplate copper on the substrate.

The present invention is also further directed to a semiconductor device containing a substrate having thereon one or more micro-sized trenches or vias having an electrolytic copper deposit obtained from the copper electroplating composition of the present invention.

### DETAILED DESCRIPTION

The present invention provides a copper electroplating composition for the metallization of micro-sized trenches or vias in a substrate, which comprises:

(1) a copper alkanesulfonate salt;

(2) a free alkanesulfonic acid; and

(3) one or more organic compounds selected from the group consisting of suppressors, accelerators, levelers, and mixtures thereof, wherein the concentration of free acid is from 0 M to about 0.25 M and the composition is free of halide ions.

In order to make the features and advantages of the present invention more comprehensible, the preferred embodiments of the present invention are described in detail below.

The copper alkanesulfonate salt in the copper electroplating composition of the present invention provides copper ions to metalize micro-sized trenches or vias in a substrate used in the manufacture of semiconductor IC devices.

A copper alkanesulfonate crystal can be used to prepare the copper electroplating composition. The copper alkanesulfonate crystal can be obtained by a simple purification procedure such as re-crystallization purification. In general, a copper alkanesulfonate solution for dissolving the copper methanesulfonate crystal in deionized water without any free acids has a pH of 1.5 to 3.5. preferably 1.7 to 3, and more preferably 1.9 to 2.7.

Other sources of copper ions may be present in the copper electroplating composition, such as copper sulfate, copper sulfamate, copper fluoroborate, copper acetate, copper pyrophosphate or copper phosphonate. The concentration of copper ions in the copper electroplating composition is preferably from about 20 to 140 g/L and more preferably from 40 to 136 g/L.

The anion of the alkanesulfonate salt present in the copper electroplating composition is represented by the formula

R—[SO₂O]⁻

wherein R is independently C₁₋₆ alkyl unsubstituted or substituted by halo, alkyl, hydroxyl, alkoxy, acyloxy, keto, carboxyl, amino, substituted amino, nitro, sulfenyl, sulfinyl, sulfonyl, mercapto, sulfonylamido, disulfonylimido, phosphino, phosphono, carbocyclic or heterocyclic

The copper electroplating composition of present invention may substantially have no free alkanesulfonic acid if a copper alkanesulfonate crystal is used. In the copper electroplating composition, the content of the free acid is generally 0 M to about 0.25 M. In a preferred embodiment the electroplating composition is essentially free of free acid. In another preferred embodiment the lower limit of free acid is 0.001 M, more preferred 0.01 M, most preferred 0.1 M. A preferred upper limit of free acid is 0.20 M, more preferred 0.15 M, even more preferred 0.10 M, most preferred 0.05 M. Particularly preferably the content of the free acid is 0 M to about 0.1 M, and more preferably 0 M to about 0.05 M.

Any acid that is solution soluble and does not otherwise adversely affect the copper electroplating composition may be used in the copper electroplating composition. Suitable acids include, but are not limited to alkanesulfonic acids, such as methanesulfonic acid, ethanesulfonic acid, propanesulfonic acid and trifluormethanesulfonmic acid; sulfuric acid; sulfamic acid; hydrochloric acid; hydrobromic acid; and fluoroboric acid. Mixtures of acids are also useful, including, but not limited to, mixtures of alkanesulfonic acids and sulfuric acid. Thus, more than one acid may be used in the present invention.

In the composition of the present invention, the content of acid(s) can be adjusted by persons having ordinary skill in the art as desired, and generally is 0 g/L to about 15 g/L, preferably 0 g/L to about 5 g/L, and more preferably 0 g/L to about 2 g/L, based on the total volume of the composition. The pH of the composition is from about 1 to about 3.6 and preferably about 1.5 to about 2.8.

In copper electroplating, additives such as accelerators (brighteners), suppressors, and levelers are typically included in the copper electroplating composition to change the electroplating behavior by improving surface deposition and thickness uniformity and enhancing chemical reactions and filling of high aspect ratio features.

The composition of the subject invention contains one or more organic compounds selected from the group consisting of accelerators, suppressors, levelers and mixtures thereof. When at least one of accelerators, suppressors, and levelers are used, the amount thereof is from about 0.2 mL/L to about 55 mL/L in total based on the volume of the composition.

The accelerators (or brighteners) are used for accelerating the size reduction of deposited particles. The accelerator typically is sulfur containing organic compounds and relatively increases the rate of copper deposition in a pattern on which a trench with a narrow width is formed. Examples of suitable accelerators are described in U.S. Pat. No. 6,679,983 including n,n-dimethyl-dithiocarbamic acid-(3-sulfopropyl)ester; 3-mercapto-propylsulfonic acid-(3-sulfopropyl)ester; 3-mercaptopropylsulfonic acid (sodium salt); carbonic acid-dithio-o-ethylester-s-ester with 3-mercapto-1-propane sulfonic acid (potassium salt); bissulfopropyl disulfide; 3-(benzthiazolyl-s-thio)propyl sulfonic acid (sodium salt); pyridinium propyl sulfobetaine; 1-sodium-3-mercaptopropane-1-sulfonate; disodium bis-(3-sulfopropyl)disulfide; or mixtures thereof. Preferably the accelerator comprises disodium bis-(3-sulfopropyl)disulfide. The concentration of the accelerator in the copper electroplating composition is preferably from about 0.5 mL/L to about 20 mL/L and more preferably from about 8 mL/L to about 15 mL/L.

The suppressors are used for increasing an over voltage for depositing a plating copper for more uniform electrodeposition. Suppressors for copper electroplating generally are oxygen-containing high-molecular-weight compounds. Suitable suppressors include, but are not limited to, carboxymethylcellulose, nonylphenolpolyglycol ether, octandiolbis-(polyalkylene glycolether), octanolpolyalkylene glycolether, oleic acidpolyglycol ester, polyethylenepropylene glycol, polyethylene glycol, polyethylene glycoldimethylether, polyoxypropylene glycol, polypropylene glycol, polyvinylalcohol, stearic acidpolyglycol ester, polyethylene oxide, stearyl alcoholpolyglycol ether, and the like. Preferably the suppressor comprises polyethylene oxide. The concentration of the suppressor in the copper electroplating composition is preferably from about 0.2 mL/L to about 10 mL/L and more preferably from about 3 mL/L to about 8 mL/L.

The levelers are used for reducing surface roughness. They are similar to suppressors that reduce the deposition rate. Levelers for copper electroplating generally comprise nitrogen-containing organic compounds. Compounds with an amino group or substituted amino groups are commonly used. Such compounds are disclosed in U.S. Pat. No. 4,376,685, U.S. Pat. No. 4,555,315, and U.S. Pat. No. 3,770,598. Examples include 1-(2-hydroxyethyl)-2-imidazolidinethione; 4-mercaptopyridine; 2-mercaptothiazoline; ethylene thiourea; thiourea; alkylated polyalkyleneimine or mixtures thereof. Preferably, the leveler is 1-(2-hydroxyethyl)-2-imidazolidinethione. The concentration of the leveler in the copper electroplating composition is preferably from about 0.5 mL/L to about 25 mL/L and more preferably from about 12 mL/L to about 20 mL/L.

The copper electroplating composition of the present invention can be used to metalize micro-sized trenches or vias in a substrate. The processing steps and operating conditions for metalizing the substrate with the copper electroplating composition of the present invention can be those for conventional processes known in the art.

The substrate to be plated is immersed in the copper electroplating composition and connected to the negative pole of a current source, thereby making it a cathode. Metallic copper anodes are also immersed in the composition and connected to the positive pole of a current source. The resulting electroplating current causes copper to electroplate on the substrate at a current density of from about 0.01 A/dm² to 5 A/dm². The method described herein allows for utilizing direct current (DC), pulse periodic current (PP), periodic pulse reverse current (PPR), and/or combinations thereof throughout the electroplating cycle.

One embodiment of the process of using the copper electroplating composition of the present invention comprises steps of immersing a substrate into the copper electroplating composition and providing electrical current through the composition to electroplating copper on the substrate so as to metalize micro-sized trenches or vias in the substrate.

The substrate contains thereon one or more micro-sized trenches or vias having an electrolytic copper deposit obtained from the copper electroplating composition of the present invention can be used to manufacture a semiconductor device.

The present invention will be further described in detail with reference to the following embodiments. However, it is understood that the descriptions are only to exemplify and illustrate the present invention and not intended to limit the scope of the present invention in any way, and changes and modifications easily made by any person of skill in the art fall within the scope of the disclosure in the present specification and the appended claims.

### EXAMPLES

### Copper Methanesulfonate Synthesis

### Example 1

A copper methanesulfonate solution was prepared by mixing 160 g copper carbonate, CuCO₃:Cu(OH)₂, 57% Cu²⁺, in 700 g deionized (DI) water. After the copper slurry was adequately mixed, 70% methanesulfonic acid of 380 g was slowly added until all the carbonate was removed.

The copper methanesulfonate solution was heated to 115° C. and then the water of the solution was distilled. After one third of the water was distilled out, the solution was slowly cooled to 20° C. to produce a crystal of copper methanesulfonate. The resultant crystal was collected and then washed twice with DI water, followed by drying at 90° C. Copper methanesulfonate solutions used to prepare copper electroplating compositions were obtained by dissolving the copper methanesulfonate crystal in DI water.

Copper Electroplating

### Examples 2 to 6

Copper electroplating compositions according to the present invention were prepared comprising the following components:
a copper methanesulfonate solution prepared as in Example 1,
CUPUR™ T 2000 as an accelerator (available from BASF, 12 mL/L),
CUPUR™ T 3000 as a suppressor (available from BASF, 6 mL/L), and

CUPUR™ T 4000 as a leveler (available from BASF, 16 mL/L).

The copper electroplating compositions of Examples 2 to 6 with different concentrations of copper ions (45, 60, 90, 120, and 136 g/L) were prepared by varying the added amount of copper methanesulfonate crystal at room temperature.

The vias had an aspect ratio of 3.6:1 (depth:opening diameter). The test wafer was degassed using CUPUR™ T 5000 (available from BASF) and then orderly immersed in DI water and the copper electroplating composition. The anode was a copper anode. The power supply supplied a current density of 0.8 A/dm². The results are shown in Table 1.

TABLE 1

| | [Cu²⁺] | | Deposition Rate |
|---|---|---|---|
| Example | (g/L) | Filling | (μm/min) |
| 2 | 45 | Void-free | 0.3 |
| | | Seam-free | |
| 3 | 60 | Void-free | 0.7 |
| | | Seam-free | |
| 4 | 90 | Void-free | 2.3 |
| | | Seam-free | |
| 5 | 120 | Void-free | 2.3 |
| | | Seam-free | |
| 6 | 136 | Void-free | 2.0 |
| | | Seam-free | |

### Examples 7 to 13 and Comparative Examples 1 to 14

The copper electroplating compositions of Examples 7 to 13 and Comparative Examples 1 to 14 were prepared with a concentration of copper ions of 90 g/L by dissolving a copper methanesulfonate crystal of 545 g in 843 g DI water. Moreover, copper electroplating compositions with different pH values and chloride concentrations were prepared. The pH of the compositions was adjusted using methanesulfonic acid (MSA) or copper hydroxide; the chloride concentration of the compositions was regulated using hydrochloric acid.

The copper electroplating steps and conditions were the same as those disclosed in Examples 2 to 6. The results are shown in Table 2.

TABLE 2

| | | pH | | Deposition |
|---|---|---|---|---|
| | Cl | (MSA | | Rate |
| | (ppm) | conc.) | Filling | (μm/min) |
| Example | | | | |
| 7 | 0 | 2.8 | Void-free | 2.3 |
| | | | Seam-free | |
| 8 | 0 | 2.2 | Void-free | 2.3 |
| | | (0M) | Seam-free | |
| 9 | 0 | 1.5 | Void-free | 2.3 |
| | | (0.01M) | Seam-free | |
| 10 | 0 | 1.0 | Void-free | 1.4 |
| | | (0.03M) | Seam-free | |
| 11 | 0 | 0.84 | Void-free | 1.8 |
| | | (0.05M) | Seam-free | |
| 12 | 0 | 0.66 | Void-free | 1.4 |
| | | (0.08M) | Seam-free | |
| 13 | 0 | 0.26 | Seam | 2.0 |
| | | (0.25M) | | |
| Comparative | | | | |
| Example | | | | |
| 1 | 50 | 2.8 | Void-free | 2.3 |
| | | | Seam-free | |
| 2 | 50 | 2.2 | Void-free | 2.2 |
| | | (0M) | Seam-free | |
| 3 | 50 | 1.5 | Void-free | 1.6 |
| | | (0.01M) | Seam-free | |
| 4 | 50 | 1.0 | Void-free | 1.2 |
| | | (0.03M) | Seam-free | |
| 5 | 50 | 0.84 | Void | 1.9 |
| | | (0.05M) | | |
| 6 | 50 | 0.66 | Void-free | 1.1 |
| | | (0.08M) | Seam-free | |
| 7 | 50 | 0.26 | Void-free | 1.0 |
| | | (0.25M) | Seam-free | |
| 8 | 100 | 2.8 | Void-free | 1.6 |
| | | | Seam-free | |
| 9 | 100 | 2.2 | Void-free | 1.1 |
| | | (0M) | Seam-free | |
| 10 | 100 | 1.5 | Void-free | 1.0 |
| | | (0.01M) | Seam-free | |
| 11 | 100 | 1.0 | Void-free | 0.9 |
| | | (0.03M) | Seam-free | |
| 12 | 100 | 0.84 | Void-free | 1.5 |
| | | (0.05M) | Seam-free | |
| 13 | 100 | 0.66 | Void-free | 1.1 |
| | | (0.08M) | Seam-free | |
| 14 | 100 | 0.26 | Void-free | 0.5 |
| | | (0.25M) | Seam-free | |

The above results show that use of a lower free acid based copper electroplating composition results in a higher deposition rate of copper. Furthermore, presence of chloride in the composition will reduce the deposition rate and cause voids. Compared to US 2009/0035940, which discloses a deposition rate of from 0.71 to 1.15 μm/min at an average current density of 0.84 A/dm², the deposition rate of the composition of Example 8 of the present invention is much higher (2.3 μm/min).

1. A copper electroplating composition, comprises comprising:
(1) a copper alkanesulfonate salt;
(2) a free alkanesulfonic acid; and
(3) one or more organic compounds selected from the group consisting of a suppressor, an accelerator, a leveler, and a mixture thereof,
wherein:
a concentration of free acid in the composition is from 0 to about 0.25 M; and the composition is free of halide ions.

2. The composition of claim 1, wherein the copper alkanesulfonate salt is obtained from a copper alkanesulfonate crystal.

3. The composition of claim 1, comprising a copper ion in a concentration of about 20 to 140 g/L.

4. The composition of claim 3, comprising a copper ion in a concentration of about 40 to 136 g/L.

5. The composition of claim 1, wherein the concentration of free acid is from 0 M to about 0.1 M.

6. The composition of claim 5, wherein the concentration of free acid is from 0 M to about 0.05 M.

7. The composition of claim 6, wherein no free acid is present in the composition.

8. The composition of claim 1, wherein the one or more organic compounds are present in an amount of from about 0.2 mL/L to about 55 mL/L, based on the volume of the composition.

9. The composition of claim 1, comprising an accelerator in a concentration of from about 0.5 to about 20 mL/L.

10. The composition of claim 9, wherein the concentration of the accelerator is from about 8 to about 15 mL/L.

11. The composition of claim 1, comprising a suppressor in a concentration of from about 0.2 to about 10 mL/L.

12. The composition of claim 11, wherein the concentration of the suppressor is from about 3 to about 8 mL/L.

13. The composition of claim 1, comprising a leveler in a concentration of from about 0.5 to about 25 mL/L.

14. The composition of claim 13, wherein the concentration of the leveler is from about 12 to about 20 mL/L.

15. The composition of claim 1, wherein an anion of the alkanesulfonate salt is represented by formula (I):
R—[SO₂O]⁻ (1)
wherein R is independently a C₁₋₆ alkyl unsubstituted or substituted by halo, alkyl, hydroxyl, alkoxy, acyloxy, keto, carboxyl, amino, substituted amino, nitro, sulfenyl, sulfinyl, sulfonyl, mercapto, sulfonylamido, disulfonylimido, phosphino, phosphono, carbocyclic or heterocyclic.

16. The composition of claim 1, wherein the alkanesulfonic acid is methanesulfonic acid, ethanesulfonic acid, propanesulfonic acid or trifluormethanesulfonmic acid.

17. The composition of claim 1, comprising a suppressor comprising carboxymethylcellulose, nonylphenolpolyglycol ether, octandiolbis-(polyalkylene glycolether), octanolpolyalkylene glycolether, oleic acidpolyglycol ester, polyethylenepropylene glycol, polyethylene glycol, polyethylene glycoldimethylether, polyoxypropylene glycol, polypropylene glycol, polyvinylalcohol, stearic acidpolyglycol ester, polyethylene oxide, stearyl alcoholpolyglycol ether or mixtures thereof.

18. The composition of claim 1, comprising an accelerator comprising n,n-dimethyl-dithiocarbamic acid-(3-sulfopropyl)ester, 3-mercapto-propylsulfonic acid-(3-sulfopropyl)ester, 3-mercaptopropylsulfonic acid (sodium salt), carbonic acid-dithio-o-ethylester-s-ester with 3-mercapto-1-propane sulfonic acid (potassium salt), bissulfopropyl disulfide, 3-(benzthiazolyl-s-thio)propyl sulfonic acid (sodium salt), pyridinium propyl sulfobetaine, 1-sodium-3-mercaptopropane-1-sulfonate, disodium bis-(3-sulfopropyl)disulfide or mixtures thereof.

19. The composition of claim 1, comprising a leveler comprising 1-(2-hydroxyethyl)-2-imidazolidinethione, 4-mercaptopyridine; 2-mercaptothiazoline, ethylene thiourea, thiourea, alkylated polyalkyleneimine or mixtures thereof.

20. The composition of claim 1, wherein a pH of the composition is from about 1 to about 3.6.

21. The composition of claim 20, wherein the pH is from about 1.5 to about 2.8.

22. A process of metalizing micro-sized trenches or vias in a substrate, the process comprising immersing a substrate into the copper electroplating composition of claim 1 and passing electrical current through the composition to electroplate copper on the substrate.

23. The process of claim 22, wherein the electrical current comprises direct current, pulse periodic current, periodic pulse reverse current or a combination thereof.

24. A semiconductor device, comprising a substrate comprising one or more micro-sized trenches or vias thereon having an electrolytic copper deposit obtained from the copper electroplating composition of claim 1.
